(19) United States
(12) Patent Application Publication
(10) Pub. No.: US 2026/0344489 A1
(43) Pub. Date: Oct. 29, 2026

(54) METHOD FOR BONDING A SEMICONDUCTOR DIE ONTO A SUBSTRATE

(71) Applicant: STATS ChipPAC Management Pte. Ltd., Singapore (SG)

(72) Inventors: HyungSuk MIN, Incheon (KR); JongChan PARK, Incheon (KR)

(21) Appl. No.: 19/655,734

(22) Filed: Apr. 23, 2026

(30) Foreign Application Priority Data
Apr. 25, 2025 (CN) 202510533135.2

(51) Int. Cl. H10W 72/00

(52) U.S. Cl. CPC H10W 72/07204; H10W 72/07235; H10W 72/07236

(57) ABSTRACT

A method for bonding a semiconductor die onto a substrate is provided. The method comprises: applying a bonding assisting layer in a first state onto a compression bonding head; picking up a semiconductor die via the compression bonding head by adhering the semiconductor die to the bonding assisting layer; displacing the compression bonding head to place the semiconductor die on a substrate; pressing the semiconductor die against the substrate by the compression bonding head; emitting a laser beam to the semiconductor die to heat solder bumps between the semiconductor die and the substrate and bond the semiconductor die to the substrate; transforming the bonding assisting layer to a second state, wherein the bonding assisting layer has a lower adhesivity to the bonding compression head in the second state than in the first state; displacing the compression bonding head to separate the bonding assisting layer from the compression bonding head.

### TECHNICAL FIELD

The present application generally relates to semiconductor technology, and more particularly, to a method for bonding a semiconductor die onto a substrate.

### BACKGROUND OF THE INVENTION

Semiconductor packaging is one of the most important parts of semiconductor manufacturing and design. The semiconductor packaging process affects power, performance, cost and basic functionalities of semiconductor packages. In a typical packaging process, semiconductor dice are first fabricated at wafer level and then each semiconductor die may be mounted onto a substrate to form an integrated semiconductor package or device.

In recent years, laser compression bonding (LCB) technology for bonding semiconductor die onto a substrate is widely adopted due to its high bonding accuracy and efficiency. During an LCB bonding process, a laser beam may be emitted to heat solder materials between the semiconductor die and the substrate, and a compression bonding head may be used to press the semiconductor die against the substrate to assist the bonding process. However, the existing bonding head may induce non-uniform heat distribution across the semiconductor die, which adversely affects the so formed bonding between the semiconductor die and the substrate.

Therefore, a need exists for a method for bonding a semiconductor die onto a substrate with improved bonding quality.

### SUMMARY OF THE INVENTION

An objective of the present application is to provide a method for bonding a semiconductor die onto a substrate with improved bonding quality.

According to an aspect of the present application, a method for bonding a semiconductor die onto a substrate is provided. The method comprises: applying a bonding assisting layer in a first state onto a compression surface of a compression bonding head; picking up a semiconductor die via the compression bonding head by adhering the semiconductor die to the bonding assisting layer; displacing the compression bonding head relative to a substrate to place the semiconductor die on the substrate, wherein solder bumps are mounted between the semiconductor die and the substrate; pressing the semiconductor die against the substrate by the compression bonding head while the bonding assisting layer remains in the first state; emitting a laser beam to the semiconductor die through the compression bonding head and the bonding assisting layer to heat the solder bumps between the semiconductor die and the substrate and bond the semiconductor die to the substrate via the solder bumps; transforming the bonding assisting layer from the first state to a second state, wherein the bonding assisting layer has a lower adhesivity to the bonding compression head in the second state than in the first state; displacing the compression bonding head relative to the substrate to separate the bonding assisting layer from the compression bonding head, and removing the bonding assisting layer from the semiconductor die.

According to another aspect of the present application, a method for bonding a semiconductor die onto a substrate is provided. The method comprises: applying a bonding assisting layer in a first state onto a top surface of a semiconductor die; picking up the semiconductor die via a compression bonding head by adhering the bonding assisting layer to the compression bonding head; displacing the compression bonding head relative to a substrate to place the semiconductor die on the substrate, wherein solder bumps are mounted between the semiconductor die and the substrate; pressing the semiconductor die against the substrate by the compression bonding head while the bonding assisting layer remains in the first state; emitting a laser beam to the semiconductor die through the compression bonding head and the bonding assisting layer to heat the solder bumps between the semiconductor die and the substrate and bond the semiconductor die to the substrate via the solder bumps; transforming the bonding assisting layer from the first state to a second state, wherein the bonding assisting layer has a lower adhesivity to the bonding compression head in the second state than in the first state; displacing the compression bonding head relative to the substrate to separate the bonding assisting layer from the compression bonding head, and removing the bonding assisting layer from the semiconductor die.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1H illustrate various steps of a method for bonding a semiconductor die onto a substrate according to a first embodiment of the present application.

FIGS. 2A to 2G illustrate various steps of a method for bonding a semiconductor die onto a substrate according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, a compression bonding device with vacuum passages may be used to bond a semiconductor die onto a substrate during an LCB bonding process. To be more specific, vacuum pressure is applied through these vacuum passages to allow the compression bonding device to pick up the semiconductor die and bond it onto a substrate via solder bumps. When the bonding process begins, a laser beam may be emitted to the semiconductor die to heat the solder bumps between the semiconductor die and the substrate. At the same time, the compression bonding device may press the semiconductor die against the substrate, thereby forming desired bonding connections therebetween. However, the vacuum passages within the compression device may adversely affect transmittance of the laser beam to the solder bumps during the laser heating process. That is, less laser radiation may reach a region of the semiconductor die beneath the vacuum passages compared with the other region of the semiconductor die which is not beneath the vacuum passages. Therefore, a temperature distribution across the semiconductor die may be in lack of uniformity, which adversely affects the bonding quality between the semiconductor die and the substrate.

To address the above issue, a method for bonding a semiconductor die onto a substrate is provided. The method introduces a bonding assisting layer which enables a compression bonding head to pick up a semiconductor die without vacuum pressure applied. The bonding assisting layer is transformable between a first state and a second state. When the bonding assisting layer is in the first state, it exhibits adhesivity that allows its adhesion onto a compression surface of the compression bonding head, which in turn provides for adhesivity for the compression bonding head. In this way, the semiconductor die can be picked up by the compression bonding head, and further be placed on the substrate and pressed against the substrate when the semiconductor die is adhered to the bonding assisting layer. Once the LCB bonding process is completed and the semiconductor die is boned onto the substrate, the bonding assisting layer is transformed to the second state. The bonding assisting layer has a lower adhesivity to the bonding compression head in the second state than in the first state, which allows for detachment of the compression bonding head from the bonding assisting layer. Finally, the bonding assisting layer can be removed from the semiconductor die, and the compression bonding head can be reused for a subsequent LCB bonding process. Since the bonding assisting layer is used, conventional vacuum passages are no longer needed for the compression bonding head. Therefore, insufficient transmittance of the laser beam through the compression bonding head, which is caused by the vacuum passages, can be successfully eliminated. This promotes uniform heat distribution across the semiconductor die and improves bonding quality between the semiconductor die and the substrate.

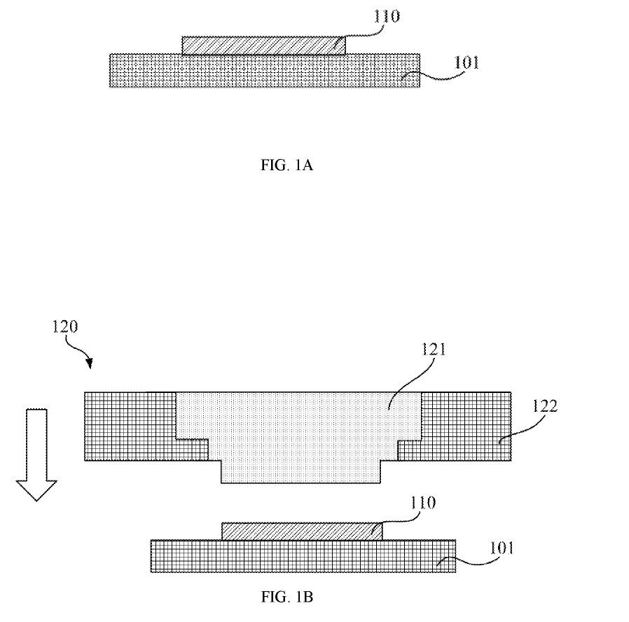

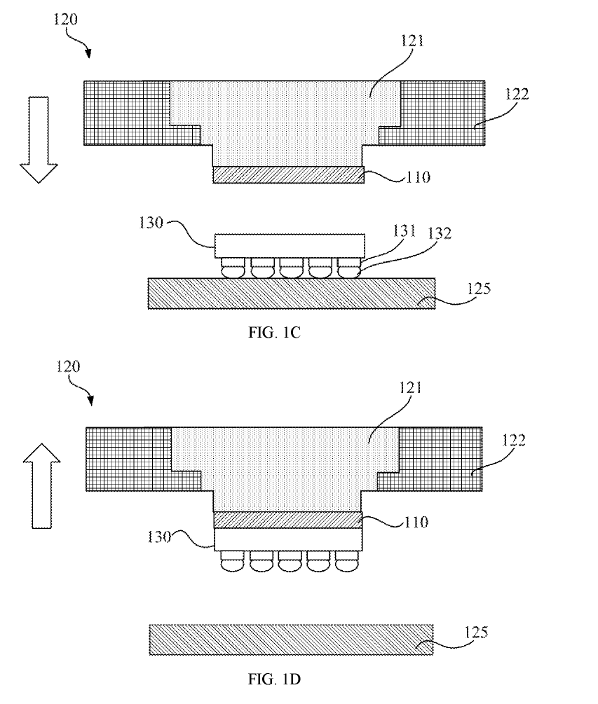

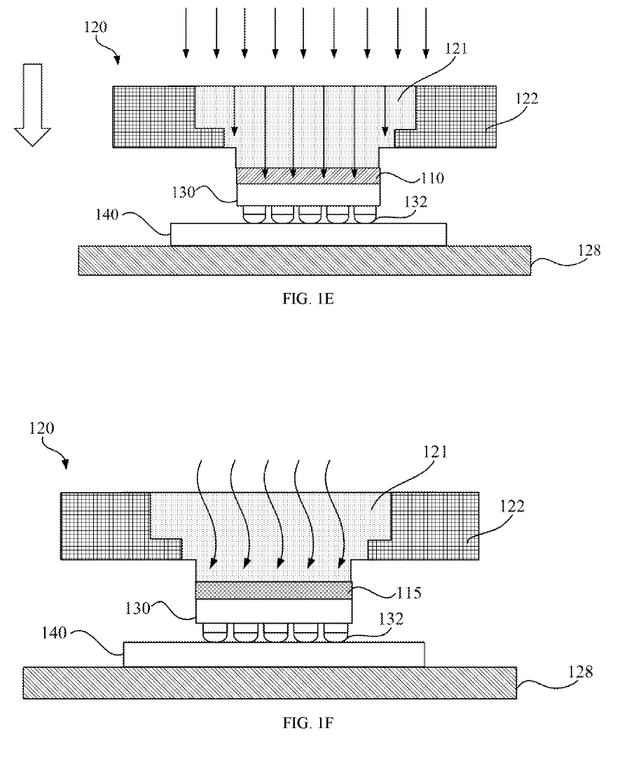

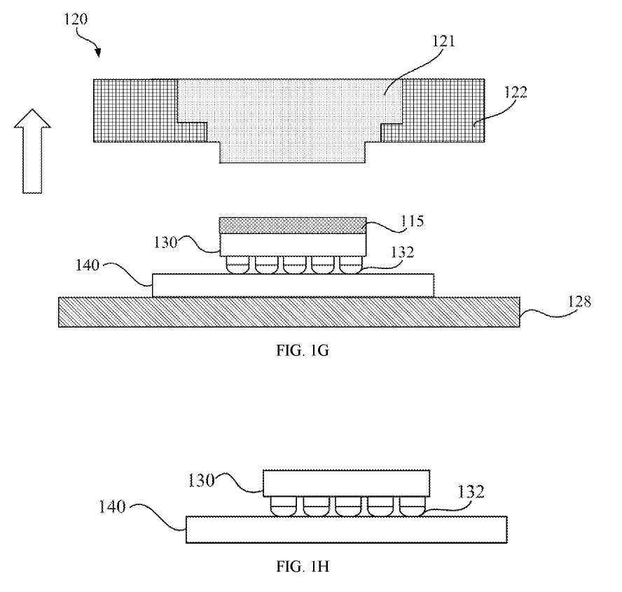

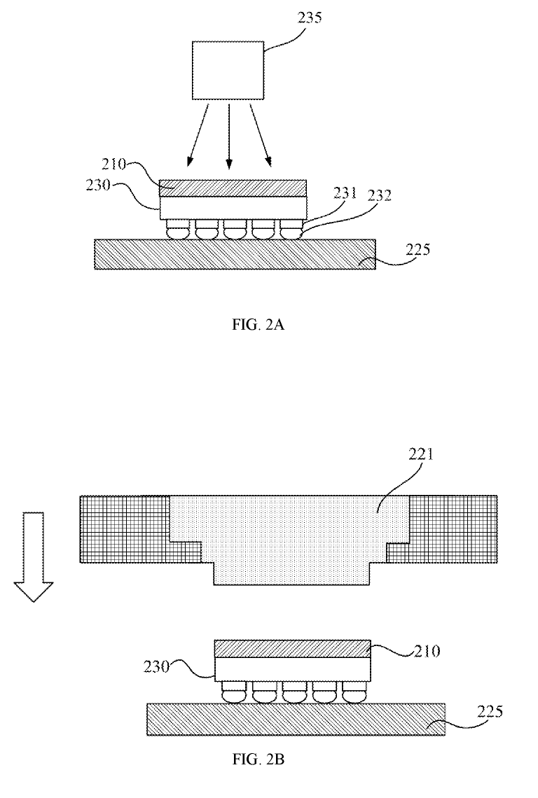

FIGS. 1A to 1H illustrate various steps of a method for bonding a semiconductor die onto a substrate according to a first embodiment of the present application.

As shown in FIG. 1A, a bonding assisting layer 110 is formed or dispensed on a processing platform 101. The bonding assisting layer 110 may be used in a bonding process to facilitate a compression bonding head to bond a semiconductor die with a substrate. At this stage, the bonding assisting layer 110 is provided in a first state, for example, in a liquid state. Also, the bonding assisting layer 110 is transparent, which allows for high transmittance of a laser beam during the subsequent bonding process.

In some embodiments, the bonding assisting layer 110 includes polydimethylsiloxane (PDMS). The PDMS material has excellent properties such as high transparency, superior flexibility, exceptional lubrication and hydrophilic property when it is in the liquid state, thereby making it an ideal bonding assisting material for the compression bonding process. In some preferred embodiments, the bonding assisting layer 110 includes ultraviolet curable polydimethylsiloxane (UV PDMS). To be more specific, the UV PDMS includes an elastomer base material (e.g., a silicone elastomer base) and a curing agent. For example, a ratio (e.g., weight ratio) of the elastomer base material and the curing agent may be ranging from 30:1 to 10:1, or preferably from 20:1 to 15:1. In some preferred embodiments, the UV PDMS may include SYLGARD™ 184 Silicone Elastomer Kit, which is commercially available.

In some other embodiments, the bonding assisting layer 110 may include ultraviolet curable silicone which have similar properties as the UV PDMS. Alternatively, the bonding assisting layer 110 may also include a liquid crystal polymer, which has low friction and high chemical resistance. These materials are suitable for use during the subsequent compression bonding process.

In some embodiments, the bonding assisting layer 110 in the first state may be formed on the processing platform 101 by jetting, spray coating, inkjet printing or any suitable deposition techniques. Before the formation of the bonding assisting layer 110 on the processing platform 101, the platform 101 may first be cleaned to remove any potential contaminants. In some preferred embodiments, the processing platform 101 may include a cavity. The bonding assisting layer 110 may be formed on a region including the cavity. The cavity may be filled with water or air to cool the bonding assisting layer 110 during its formation.

Next, as shown in FIG. 1B, a compression bonding head 121 is provided. The compression bonding head 121 is used to apply a required press force to bond a semiconductor die onto a substrate. The compression bonding head 121 may further include a base portion and a convex portion extending upward from the base portion. The convex portion may be attached on a bottom surface of the base portion or formed with the base portion. During a subsequent process, a bottom surface of the convex portion may be close to the semiconductor die, or in particular in indirect contact with the semiconductor die via the bonding assisting layer 110, when the semiconductor die is picked up by the compression bonding head 121. In some embodiments, the size of the convex portion may be substantially equal to or smaller than that of the base portion. In some embodiments, the convex portion may have a rectangular layout, which may be similar to a shape of the semiconductor die. In some other embodiments, the convex portion may have other shaped layouts, such as a circle, a hexagon or an octagon. In some embodiments, the base portion may have a stepwise layout, that is, a part of the base portion closer to the convex portion may have a smaller size compared with another part of the base portion away from the convex portion. In some other embodiments, the base portion may have a size or layout that is the same as that of the convex portion. It can be appreciated that the convex portion may be formed separately from the base portion, or may be integrally formed with the base portion as a single piece. In this embodiment, the compression bonding head 121 includes a material transparent to laser radiation, which may include at least one material selected from the following group: Al₂O₃, sapphire, quartz and glass. The compression bonding head 121 allows a laser beam, which is applied in following processes, to substantially pass through the compression bonding head 121 and reach the semiconductor die. Additionally, a compression holder 122 is disposed outside of the compression bonding head 121, which mates with the compression bonding head 121 in size and shape to securely hold the compression bonding head 121. The compression holder 122 can provide mechanical support for the compression bonding head 121 when it is being used in the bonding process. In some embodiments, the compression holder 122 may include a light shading material which blocks laser beam to pass therethrough. It should be noted that no vacuum passages are needed within the compression bonding head 121, thereby simplifying the formation of the compression bonding head 121 and reducing a production cost. The compression bonding head 121 and the compression holder 122 together form a compression bonding member 120. Furthermore, a rail is coupled to the compression bonding member 120 and allows the compression bonding member 120 to be moved vertically and/or horizontally with respect to a working platform. In some embodiments, a drive mechanism may be mounted on the rail to control the movement of the compression bonding member 120.

In some embodiments, the bonding assisting layer 110 in the first state may have a surface energy ranging between 30 mJ/m² and 40m J/m², which exhibits a hydrophilic property. Also, a bottom surface of the compression bonding head 121 may have a surface energy ranging between 45 mJ/m² and 60 mJ/m², which also exhibits a hydrophilic property. As shown in FIG. 1B, the compression bonding head 121 is moved downward towards the bonding assisting layer 110 until it is in contact with the bonding assisting layer 110. Due to a relatively high adhesivity of the bonding assisting layer 110 to the compression bonding head 121 caused by its hydrophilic property, the bonding assisting layer 110 may securely adhere onto the bottom surface (i.e., the compression surface) of the compression bonding head 121. Further, the adhesivity of the bonding assisting layer 110 to the processing platform 101 may be lower than to the compression bonding head 121. As such, when the compression bonding head 121 is moved upward away from the processing platform 101, the bonding assisting layer 110 can be released from the processing platform 101 and attached on the bottom surface of the compression bonding head 121.

Next, as shown in FIG. 1C, the compression bonding head 121 is moved towards a carrier 125 where a semiconductor die 130 is placed. The carrier 125 may be used in previous fabrication processes, for example, a flipper 125. In some embodiments, the semiconductor die 130 may include a flip chip, or some large-scale semiconductor chips such as a System-on-a-Chip (SOC) die. Conductive pads 131 may be formed on a bottom surface of the semiconductor die 130 with solder bumps 132 formed thereon. Moreover, the semiconductor die 130 may include a silicon wafer die, for example, having an oxide top surface. The top surface of the semiconductor die 130 may have a surface energy ranging between 40 mJ/m² and 60 mJ/m², which exhibits a hydrophilic property.

In some embodiments, the compression bonding head 121 with the bonding assisting layer 110 may be positioned directly above the semiconductor die 130 for optimal attachment between them. Next, the compression bonding head 121 is moved downward towards the semiconductor die 130 until the bonding assisting layer 110 is in contact with the top surface of the semiconductor die 130. Due to adhesivity of the bonding assisting layer 110 to the semiconductor die 130, the top surface of the semiconductor die 130 adheres onto the bonding assisting layer 110. Therefore, the semiconductor die 130 is indirectly attached to the compression surface of the compression bonding head 121 through the bonding assisting layer 110. Next, the compression bonding head 121 is moved away from the carrier 125 with the semiconductor die 130 attached thereon such that the semiconductor die 130 is picked up by the compression bonding head 121, as shown in FIG. 1D.

In some embodiments, a thickness of the bonding assisting layer 110 may be 200µm to 1500µm to provide sufficient adhesion force to the semiconductor die 130. It can be appreciated that the thickness of the bonding assisting layer 110 may be proportional to a weight of the semiconductor die 130. For example, for a medium-sized semiconductor die 130 which has a dimension of approximately 30mm in both length and width, a thickness of the bonding assisting layer 110 may be 200µm to 500µm to guarantee stable pick up of the semiconductor die 130. For a large-sized semiconductor die 130 which has a dimension of approximately 60mm in both length and width, a thickness of the bonding assisting layer 110 may be 800µm to 1500µm to allow for uniform adhesion between the semiconductor die 130 and the compression bonding head 121, so that the semiconductor die 130 can be picked up stably.

In some preferred embodiments, the semiconductor die 130 may be weighted before being picked up, and an algorithm may be used to calculate a required thickness of the bonding assisting layer 110 to allow for sufficient adhesion force for die pick-up.

Next, as shown in FIG. 1E, the semiconductor die 130 is displaced by the compression bonding head 121 to a position above a substrate 140. The semiconductor die 130 may be bonded onto the substrate 140 in the subsequent bonding process. In some embodiments, the substrate 140 may be made of silicon or other semiconductor materials, or may include a printed circuit board (PCB), a ceramic substrate, a laminate interposer, a strip interposer, a leadframe, or other suitable substrates. In some examples, the substrate 140 may include redistribution layers or structures having one or more dielectric layers and one or more conductive layers between and through dielectric layers. Thus, various components and other structure on either one side or both sides of the substrate 140 may be electrically coupled with each other to form an integrated electronic system. In this embodiment, the substrate 140 is placed on a substrate carrier 128 for mechanical support. In some embodiments, the substrate carrier 128 may have air vents (e.g., pores) which are fluidly coupled to a vacuum source, so as to apply a vacuum pressure to the substrate 140 when it is disposed on the substrate carrier 128. The attraction force applied onto the substrate 140 which is generated by the vacuum pressure may reduce warpage of the substrate 140 during the subsequent bonding process. Multiple sets of conductive pads can be formed on a top surface of the substrate 140 for the mounting of the semiconductor die 130 on the substrate 140. In some other embodiments, an additional solder paste may be dispensed on the sets of conductive pads to facilitate the subsequent bonding process. Next, the compression bonding head 121 together with the semiconductor die 130 are moved downward towards the substrate carrier 128 to place the semiconductor die 130 onto the substrate 140 with the solder bumps 132 mounted therebetween.

Next, a laser beam is emitted from a laser source (not shown) disposed above the compression bonding head 121 to the substrate carrier 128 to conduct the bonding process. The laser beam passes through the compression bonding head 121 and the bonding assisting layer 110 to reach the semiconductor die 130, so as to heat the semiconductor die 130 and the solder bumps 132 between the semiconductor die 130 and the substrate 140. In some embodiments, a press force may also be applied to the semiconductor die 130 by the compression bonding head 121 to assist the bonding process.

In some embodiments, the semiconductor die 130 may be heated gradually by the laser beam. For example, the semiconductor die 130 may first be preheated to a temperature between 85° C and 150° C. In some preferred embodiments, the semiconductor die 130 may be preheated to a temperature about 90° C. The preheating process may last for a period of 2 seconds to 20 seconds, or preferably, 10 seconds to 20 seconds. In this embodiment, the preheating process may release thermal stress within the semiconductor die 130 and thus reduce warpage of the semiconductor die 130 generated in previous processes. For example, the preheating process may transform the semiconductor die 130 with a convex or concave shape to an almost flat shape, which facilitates subsequent processes. In addition, the preheating of the semiconductor die 130 and the solder bumps 132 may also reduce heat energy and a heating duration needed in the subsequent bonding process. Next, the laser beam may continue to heat the semiconductor die 130 and the solder paste or solder bumps such that all the solder paste may be heated sufficiently, for example, to a temperature above its melting temperature, which may be referred to as a bonding heating process. During the bonding heating process, the semiconductor die 130 is pressed against the substrate 140 via a press force applied by the compression bonding head 121 to reshape the solder bumps 132 to allow for their sufficient infiltration on the substrate 140. This allows the solder bumps 132 to electrically connect the semiconductor die 130 with the substrate 140, thereby bonding the semiconductor die 130 to the substrate 140 via the solder bumps 132. During this compression process, the bonding assisting layer 110 in the first state (e.g., the liquid state) may serve as a buffer layer to alleviate collision between the compression bonding head 121 and the semiconductor die 130. This reduces mechanical damages to the semiconductor die 130 and the solder bumps 132 when they are being pressed, which further improves the reliability of bonding connections so formed. Next, the press force applied by the compression bonding head 121 may gradually decrease to allow for solidification of the solder bumps 132. In some other embodiments, the pre-heating process is not needed, and the process of pressing the semiconductor die 130 against the substrate 140 is performed simultaneously with the entire process of emitting the laser beam to the semiconductor die 130. During the compression bonding process, the semiconductor die 130 is bonded onto the substrate 140 via the solder bumps 132 with an in-situ bonding mechanism without self-alignment of the solder bumps 132 with conductive pads on the substrate 140, which may have higher bonding efficiency and accuracy compared with conventional thermal bonding processes or laser assisted bonding processes. It should be noted that the bonding assisting layer 110 remains in the first state, e.g., in the liquid state when the semiconductor die 130 is pressed against the substrate 240 to facilitate the compression bonding process.

During the bonding process, since the bonding assisting layer 110 is used to conduct the compression process, conventional vacuum passages are no longer needed in the compression bonding head 121. Therefore, the laser beam emitted from the laser source may be effectively transmitted through the compression bonding head 121. Additionally, the bonding assisting layer 110 is transparent to the laser beam such that the laser beam can pass through the compression bonding head 121 and the bonding assisting layer 110 with almost lossless energy transmittance to reach the semiconductor die 130 and the solder bumps 132. In this way, all the regions of the semiconductor die 130 and the solder bumps 132 may receive sufficient and uniform laser radiation for the bonding process. This promotes uniform heat distribution across the semiconductor die 130 and improves bonding quality between the semiconductor die 130 and the substrate 140. Furthermore, during the laser heating process, the bonding assisting layer 110 may have a relatively stable property when it is exposed to the laser beam, which enables it to remain in the first state (e.g., the liquid state) to facilitate the implementation of the entire compression bonding process to achieve improved bonding connections.

Next, after the solder bumps 132 between the semiconductor die 130 and the substrate 140 are solidified, the laser source may be turned off. Then the heating process implemented to the semiconductor die 130 and the solder bumps 132 is terminated, and the temperature of the semiconductor die 130 and the solder bumps 132 may begin to decrease to a lower temperature such as the room temperature or higher. During the cooling of the solder bumps 132, the compression bonding head 121 may maintain at the bonding position for a while to help the solder bumps 132 solidify with a required bump height. Afterwards, the force applied by the compression bonding head 121 may also be removed and the shape of the solder bumps 132 may not change, which enables stable bonding connections between the semiconductor die 130 and the substrate 140 and thereby completes the bonding process.

Next, as shown in FIG. 1F, after the bonding process, ultraviolet radiation (UV radiation) is emitted from a light source above the compression bonding head 121. The UV radiation passes through the compression bonding head 121 to reach the bonding assisting layer 110 to transform it form the first state (e.g., the liquid state) to the second state. In some embodiments, such as the embodiment shown in FIG. 1F, the bonding assisting layer 110 in the liquid state is cured and be transformed into a solidified bonding assisting layer 115 in a solid state. To be more specific, when the UV radiation is applied to the bonding assisting layer 110, the material of the layer, for example, the PDMS material may undergo crosslinking reactions to form covalent bridges within the material and may establish a 3D network in the material. In this way, the PDMS material may transform from a viscous liquid state to an elastomeric solid state. During the curing process of the bonding assisting layer 110, the surface energy of the bonding assisting layer 110 is decreased, and thus the surface of the bonding assisting layer 110 may be gradually transformed from a hydrophilic surface to a hydrophobic surface. Consequently, the adhesivity of the bonding assisting layer 110 to the external surface, such as the compression surface of the compression bonding head 121, is also decreased. In some embodiments, the adhesivity of the bonding assisting layer 110 may at least be reduced to a point such that the solidified bonding assisting layer 115 has a lower adhesive force to the compression bonding head 121 than to the semiconductor die 130. In some preferred embodiments, the surface energy of the solidified bonding assisting layer 115 may be reduced to 19 mJ/m² to 22 mJ/m². Therefore, the curing process is completed, resulting in the solidified bonding assisting layer 115 with the hydrophobic surface and the low adhesivity.

In some other embodiments, the bonding assisting layer 110 may include ultraviolet curable silicone, which may be cured by a similar process as the PDMS. In some alternative embodiments, the bonding assisting layer 110 may include liquid crystal polymer. The liquid crystal polymer can be cured through either a UV radiation process or a heating process.

Next, as shown in FIG. 1G, the compression bonding head 121 is displaced relative to the substrate 140. In particular, the compression bonding head 121 is moved upward to keep away from the substrate carrier 128. Since the solidified bonding assisting layer 115 has a lower adhesive force to the compression bonding head 121 than to the semiconductor die 130, the solidified bonding assisting layer 115 can be separated from the compression bonding head 121 at the compression surface but still maintains adhesion to the semiconductor die 130 when exposed to an external force.

Next, the solidified bonding assisting layer 115 is removed from the semiconductor die 130, as shown in FIG. 1H. In some preferred embodiments, a deflux process is implemented to remove the solidified bonding assisting layer 115 while simultaneously removing residual flux from the solder bumps 132. By applying the deflux process to the semiconductor die 130 and the solidified bonding assisting layer 115, the compression surface of the compression bonding head 121 may remain uncontaminated, thereby ensuring reliable performance on subsequent bonding processes. In this way, the semiconductor die 130 is bonded onto the substrate 140 with improved bonding quality for subsequent processes.

In some other embodiments, the bonding assisting layer 115 may have a lower adhesive force to the semiconductor die 130 than to the compression bonding head 121. Therefore, the bonding assisting layer 115 can be separated from the semiconductor die 130 but still maintains adhesion to the compression bonding head 121. The bonding assisting layer 115 can then be removed from the compression bonding head 121 to expose the compression surface again for subsequent bonding processes.

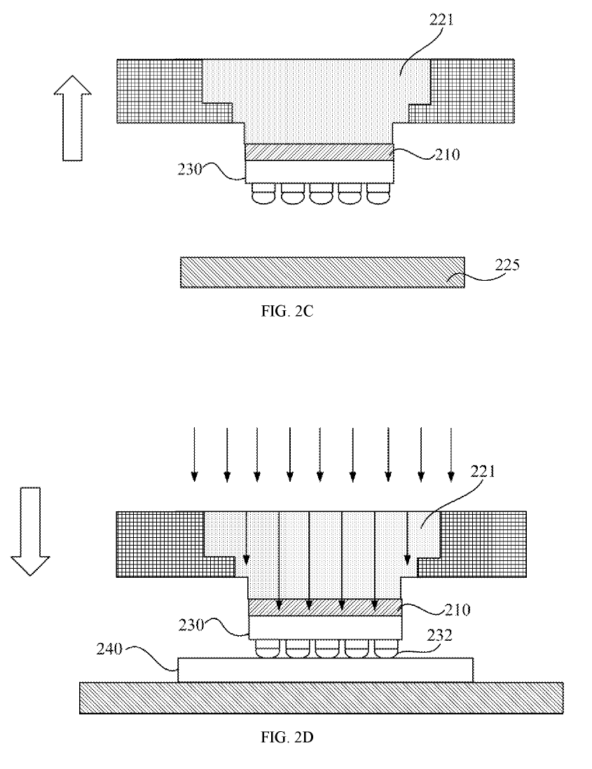

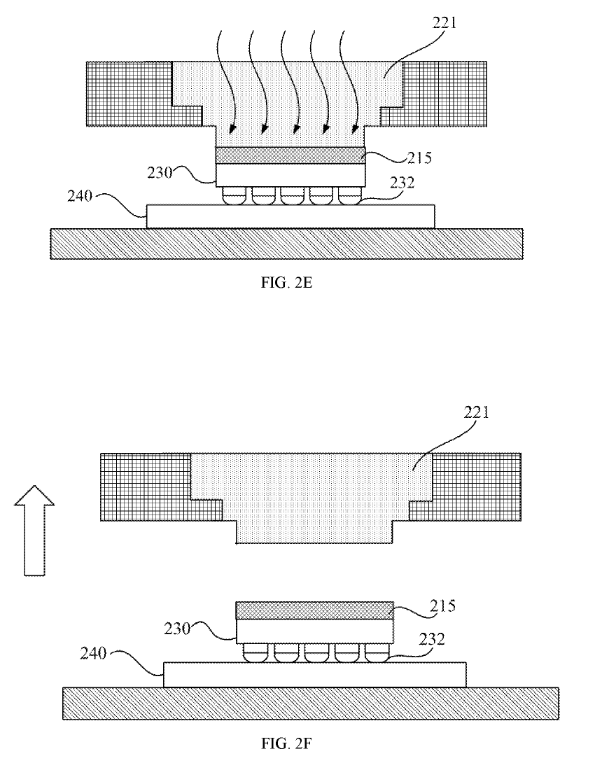

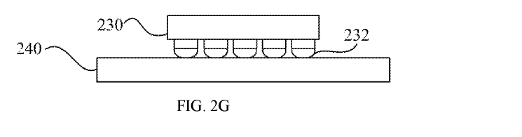

FIGS. 2A to 2G illustrate various steps of a method for bonding a semiconductor die onto a substrate according to a second embodiment of the present application. The method illustrated in FIGS. 2A to 2G is generally the same as the method illustrated in FIGS. 1A to 1H, except that in FIG. 2A, a bonding assisting layer is first applied to a semiconductor die instead of being applied to a compression bonding head as shown in FIGS. 1A to 1C.

As shown in FIG. 2A, a semiconductor die 230 is placed on a carrier 225 (e.g., a flipper). In some embodiments, conductive pads 231 may be formed on a bottom surface of the semiconductor die 230 with solder bumps 232 formed thereon. A bonding assisting layer 210 is formed on a top surface of the semiconductor die 230 when the bonding assisting layer 210 is in a first state, for example, in a liquid state. In some embodiments, the bonding assisting layer 110 includes polydimethylsiloxane (PDMS). In some preferred embodiments, the bonding assisting layer 210 in the liquid state may be formed on the semiconductor die 230 by a jetting process. In particular, a raw material of the bonding assisting layer 210 may be provided in a storage block 235 first, and then be liquified and jetted from an outlet of the storage block 235. The bonding assisting layer 210 in the liquid state may have sufficient ductility to uniformly extend across the entire top surface of the semiconductor die 230, which provides a maximum contact area for subsequent attachment with a compression bonding head. Additionally, the bonding assisting layer 210 can be formed according to a size and layout of the top surface of the semiconductor die 230, which is also beneficial for the subsequent attachment with the compression bonding head 221. In some other embodiments, the bonding assisting layer 210 may be formed by spray coating, inkjet printing or any suitable deposition techniques. The bonding assisting layer 210 in the liquid state may have a surface energy ranging between 30 mJ/m² and 40 mJ/m², which exhibits a hydrophilic property. Additionally, the top surface of the semiconductor die 230 may have a surface energy ranging between 40 mJ/m² and 60 mJ/m², which also exhibits a hydrophilic property. Due to adhesivity of the bonding assisting layer 210 to the semiconductor die 230 caused by their hydrophilic properties, the bonding assisting layer 210 may securely adhere onto the top surface of the semiconductor die 230. It should be noted that details of the material, the properties, and the structure of the semiconductor die 230 and the bonding assisting layer 210 may be similar to those illustrated with respect to the embodiments shown in FIGS. 1A to 1C, which will not be elaborated in detail here for simplicity.

Next, as shown in FIG. 2B, a compression bonding head 221 is provided. A bottom surface, i.e., a compression surface of the compression bonding head 221 may have a surface energy ranging between 45 mJ/m² and 60 mJ/m². The compression bonding head 221 is moved downward towards the bonding assisting layer 210 and the semiconductor die 230 until it is in contact with a surface of the bonding assisting layer 210. Similarly, due to adhesivity of the bonding assisting layer 210 to the compression bonding head 221, the bonding assisting layer 210 adheres onto the compression surface of the compression bonding head 221. Therefore, the semiconductor die 230 is indirectly attached to the compression surface of the compression bonding head 221 through the bonding assisting layer 210. Next, the compression bonding head 221 is moved upward with the semiconductor die 230 attached thereon such that the semiconductor die 230 is picked up by the compression bonding head 221 as shown in FIG. 2C.

Next, as shown in FIG. 2D, the semiconductor die 230 is displaced by the compression bonding head 221 to a position above a substrate 240. Next, the compression bonding head 221 together with the semiconductor die 230 is moved downward towards the substrate 240 to place the semiconductor die 230 onto the substrate 240 with the solder bumps 232 mounted therebetween.

Next, a laser beam is emitted from a laser source (not shown) disposed above the compression bonding head 221 to the substrate 240 to conduct the bonding process. The laser beam passes through the compression bonding head 221 and the bonding assisting layer 210 to reach the semiconductor die 230, so as to heat the semiconductor die 230 and the solder bumps 232. During the bonding process, the semiconductor die 230 is pressed against the substrate 240 by the compression bonding head 221 to reshape the solder bumps 232 to allow for their sufficient infiltration on the substrate 240. This allows the solder bumps 232 to electrically connect the semiconductor die 230 with the substrate 240, thereby bonding the semiconductor die 230 to the substrate 240 via the solder bumps 232. It should be noted that the bonding assisting layer 210 remains in the first state, e.g., in the liquid state when the semiconductor die 230 is pressed against the substrate 240 to facilitate the compression bonding process. Details of the compression bonding process may be similar to those illustrated with respect to the embodiments shown in FIG. 1E, which will not be elaborated in detail here for simplicity.

Next, as shown in FIG. 2E, after the bonding process, ultraviolet radiation (UV radiation) is emitted from a light source above the compression bonding head 221. The UV radiation passes through the compression bonding head 221 to reach the bonding assisting layer 210 to transform it form the first state (e.g., the liquid state) to a second state. In some embodiments, such as the embodiment shown in FIG. 2E, the bonding assisting layer in the liquid state 210 is cured and be transformed into a solidified bonding assisting layer 215 in a solid state, i.e., the second state. To be more specific, when the UV radiation is applied to the bonding assisting layer 210, the material of the layer, for example, the PDMS material, may transform from a viscous liquid state to an elastomeric solid state. The solidified bonding assisting layer 215 may have hydrophobic surface with low surface energy, and thereby have a lower adhesivity to the compression bonding head 221 than in the liquid state. More specifically, the solidified bonding assisting layer 215 may have a lower adhesive force to the compression bonding head 221 than to the semiconductor die 230.

In some other embodiments, the bonding assisting layer 210 may include ultraviolet curable silicone, which may be cured by a similar process as the PDMS. In some alternative embodiments, the bonding assisting layer 210 may include liquid crystal polymer. The liquid crystal polymer can be cured through either a UV radiation process or a heating process.

Next, as shown in FIG. 2F, the compression bonding head 221 is displaced relative to the substrate 240. In particular, the compression bonding head 221 is moved upward to keep away from the substrate 240. Since the solidified bonding assisting layer 215 has a lower adhesive force to the compression bonding head 221 than to the semiconductor die 230, the solidified bonding assisting layer 215 can be separated from the compression bonding head 221 at the compression surface when exposed to an external force, but still maintains adhesion to the semiconductor die 230.

Next, as shown in FIG. 2G, the solidified bonding assisting layer 215 is removed from the semiconductor die 230 by a deflux process, for example. In this way, the semiconductor die 230 is bonded onto the substrate 240 with improved bonding quality for subsequent processes.

More details of the step of transforming the bonding assisting layer 210 from the first state to the second state, the properties of the bonding assisting layer in the second state 215 and the step of separating the bonding assisting layer 215 from the compression bonding head 221 may be similar to those illustrated with respect to the embodiments shown in FIGS. 1F to 1H, which will not be elaborated in detail here for simplicity.

While the exemplary method for bonding a semiconductor die onto a substrate of the present application is described in conjunction with corresponding figures, it will be understood by those skilled in the art that modifications and adaptations to the method may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for bonding a semiconductor die onto a substrate, the method comprising:
applying a bonding assisting layer in a first state onto a compression surface of a compression bonding head;
picking up a semiconductor die via the compression bonding head by adhering the semiconductor die to the bonding assisting layer;
displacing the compression bonding head relative to a substrate to place the semiconductor die on the substrate, wherein solder bumps are mounted between the semiconductor die and the substrate;
pressing the semiconductor die against the substrate by the compression bonding head while the bonding assisting layer remains in the first state;
emitting a laser beam to the semiconductor die through the compression bonding head and the bonding assisting layer to heat the solder bumps between the semiconductor die and the substrate and bond the semiconductor die to the substrate via the solder bumps;
transforming the bonding assisting layer from the first state to a second state, wherein the bonding assisting layer has a lower adhesivity to the bonding compression head in the second state than in the first state;
displacing the compression bonding head relative to the substrate to separate the bonding assisting layer from the compression bonding head, and
removing the bonding assisting layer from the semiconductor die.

2. The method of claim 1, wherein the bonding assisting layer has higher surface energy in the first state than in the second state.

3. The method of claim 2, wherein the first state of the bonding assisting layer is a liquid state, and the second state of the bonding assisting layer is a solid state.

4. The method of claim 3, wherein the bonding assisting layer comprises ultraviolet curable polydimethylsiloxane.

5. The method of claim 4, wherein the ultraviolet curable polydimethylsiloxane comprises a silicone elastomer base and a curing agent.

6. The method of claim 5, wherein a ratio of the silicone elastomer base and the curing agent is 20:1 to 15:1.

7. The method of claim 1, wherein the step of transforming the bonding assisting layer from the first state to a second state further comprises:
reducing the adhesivity of the bonding assisting layer till that the bonding assisting layer has a lower adhesive force to the compression bonding head than to the semiconductor die.

8. The method of claim 1, wherein the step of pressing the semiconductor die against the substrate is performed simultaneously with the step of emitting the laser beam to the semiconductor die, and wherein the bonding assisting layer remains in the first state during the step of emitting a laser beam to the semiconductor die.

9. The method of claim 1, wherein the step of transforming the bonding assisting layer from the first state to a second state is performed after the step of emitting the laser beam to the semiconductor die.

10. The method of claim 4, wherein transforming the bonding assisting layer from the first state to a second state comprises: curing the bonding assisting layer from the first state to the second state by applying ultraviolet radiation to the bonding assisting layer.

11. The method of claim 3, wherein the bonding assisting layer comprises ultraviolet curable silicone.

12. The method of claim 3, wherein the bonding assisting layer comprises liquid crystal polymer.

13. The method of claim 11, wherein transforming the bonding assisting layer from the first state to a second state comprises: curing the bonding assisting layer from the first state to the second state by applying ultraviolet radiation or heat to the bonding assisting layer.

14. The method of claim 1, wherein the bonding assisting layer in the first state is formed by using a processing platform comprising a cavity, wherein the cavity is configured for applying air or water to cool the bonding assisting layer.

15. A method for bonding a semiconductor die onto a substrate, the method comprising:
applying a bonding assisting layer in a first state onto a top surface of a semiconductor die;
picking up the semiconductor die via a compression bonding head by adhering the bonding assisting layer to the compression bonding head;
displacing the compression bonding head relative to a substrate to place the semiconductor die on the substrate, wherein solder bumps are mounted between the semiconductor die and the substrate;
pressing the semiconductor die against the substrate by the compression bonding head while the bonding assisting layer remains in the first state;
emitting a laser beam to the semiconductor die through the compression bonding head and the bonding assisting layer to heat the solder bumps between the semiconductor die and the substrate and bond the semiconductor die to the substrate via the solder bumps;
transforming the bonding assisting layer from the first state to a second state, wherein the bonding assisting layer has a lower adhesivity to the bonding compression head in the second state than in the first state;
displacing the compression bonding head relative to the substrate to separate the bonding assisting layer from the compression bonding head, and
removing the bonding assisting layer from the semiconductor die.

16. The method of claim 15, wherein the bonding assisting layer has higher surface energy in the first state than in the second state.

17. The method of claim 16, wherein the first state of the bonding assisting layer is a liquid state, and the second state of the bonding assisting layer is a solid state.

18. The method of claim 17, wherein the bonding assisting layer comprises ultraviolet curable polydimethylsiloxane, ultraviolet curable silicone or liquid crystal polymer.
